(19) United States
(12) Patent Application Publication
(10) Pub. No.: US 2017/0211791 A1
(43) Pub. Date: Jul. 27, 2017

(54) Encapsulated LED Module with Ceramic Circuit Board and Driver Module for Mains Voltage

(71) Applicant: CERAMTEC GMBH, Plochingen (DE)

(72) Inventors: Marco HEINRICH, Arzberg (DE); Anton GSCHWANDLER, Mering (DE)

(21) Appl. No.: 15/039,605

(22) PCT Filed: Nov. 26, 2014
(86) PCT No.: PCT/EP14/75646

§ 371 Date: May 26, 2016

(30) Foreign Application Priority Data
Nov. 27, 2013 (DE) 10 2013 224 256.5

(51) Int. Cl. F21V 23/00; F21V 29/85; F21V 3/04; H05K 1/18; F21V 23/06

(52) U.S. Cl. CPC F21V 23/005; H05K 1/181; F21V 23/06; F21V 3/0436; F21V 29/86; H05K 2201/10106; H05K 2201/10287

(57) ABSTRACT

The invention relates to an LED module having a support body, on the surface of which metallization regions forming a circuit board are arranged and on which LEDs are mounted. In order that the LED module is immediately ready for use, i.e. can be connected directly to a power supply, according to the invention, it is proposed that, in addition to the LEDs, the driver modules thereof are also mounted on the metallization regions and at least the LEDs together with the driver modules are covered by a light-transmitting material, electrical connecting elements are connected to the LEDs or driver modules and are fed out of the translucent material.

The invention relates to an LED module having a support body, on the surface of which metallization regions forming a circuit board are arranged and on which LEDs are mounted.

LED modules having supports made of plastic or metals such as aluminum or steel (e.g. encompassed by non-conductors such as enamel or ceramic) and with coating materials, which are not cast, over the LEDs are known. The driver circuits are spatially separated.

The invention is based on the object of supplementing an LED module according to the pre-characterizing clause of claim 1 such that it is immediately ready for use, i.e. can be connected directly to a power supply.

According to the invention, this object is achieved in that, in addition to the LEDs, the driver modules thereof are also mounted, preferably soldered, on the metallization regions and at least the LEDs together with the driver modules are covered by a light-transmitting material, electrical connecting elements are connected to the LEDs or driver modules and are fed out of the light-transmitting material. By covering with the light-transmitting material, the LEDs and the driver modules are protected against moisture and environmental influences, wherein the light generated by the LEDs can emanate virtually unhindered from the LED module. The LED module can easily be connected to a power supply by means of the electrical connecting elements. “Covered by a light-transmitting material” is also understood to mean “encapsulated by a light-transmitting material”.

A plate-like design of the support body is preferred. In special embodiments, the support body can also be curved. For example, the support body can be in the form of a tube.

The support body is preferably made of a ceramic material. This could be aluminum oxide or aluminum nitride. Ceramic materials have a high dielectric strength and adequate thermal conduction. In the case of ceramics, the metallization regions which form the circuit board are advantageously sintered with the support body. For this purpose, the metallization regions are printed onto the green body and then sintered, or the metallization regions are printed onto the sintered or sintered-on support body and then sintered. In both cases, the heat dissipation from the LEDs and driver modules into the ceramic is extremely good. Driver modules are understood to mean all electrical and electronic components which are necessary for connecting the LEDs to a power supply.

Alternatively, the support body can also consist of a ceramic composite, glass, glass ceramic or high-purity crystalline ceramics. The metallization regions are advantageously soldered or glued onto the support body or sintered with the support body.

The electrical connecting elements are either connecting leads or plug-in connectors which are fed out of the covering with the light-transmitting material. Light-transmitting material is understood to be a translucent material. Covering is also understood to mean an encapsulation.

The light-transmitting material preferably covers the whole surface of the support body on which the LEDs and the driver modules are located. Only the connecting elements are fed out.

Preferably, the light-transmitting material is a plastic or consists of a plastic-based material.

The invention therefore describes an LED module, flat or curved, having one or more LEDs or LED modules. These are mounted (soldered, glued, sintered) together with the associated driver modules (one or more components of drivers or drivers+resistors) on a circuit board made of ceramic or ceramic composite or glass or glass ceramic or high-purity crystalline ceramics (if necessary metalized) and coated (covered) with a light-transmitting material. The module can have a plug-in connector or be directly soldered (or bonded or connected in some other manner) to connecting leads. The module can be connected directly by means of a mains plug on a power lead/connector to 110 or 220 V for example.

Advantage: a high level of protection against contact is achieved as a result of the non-conducting ceramic or glass plate. Protection class IP 44 or higher can be achieved. Electrical protection class II can also be achieved. The LED module can be connected directly to a mains voltage. This covers Asiatic and American as well as European mains voltages. Dust-tightness is achieved by the cover (covered by the protection class IP 44). The LED module can be mounted in many ways (glued, clamped, screwed, clipped).

The invention is explained further below with reference to three figures.

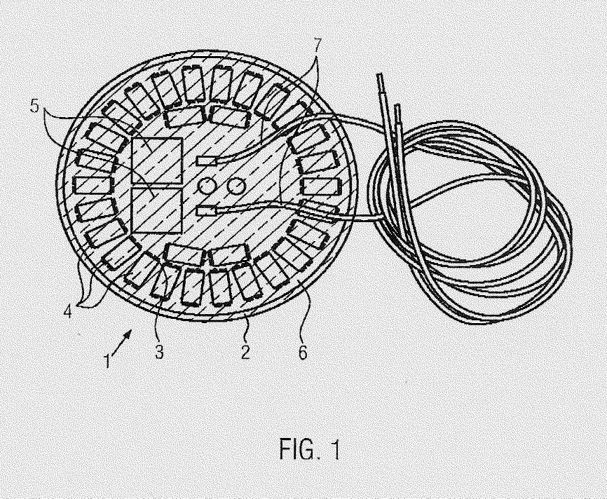

FIG. 1 shows an example of a round LED module 1 having a round support body 2. Sintered metallization regions 3 are located thereon. These form a circuit board on which LEDs 4 in the form of a circle and the associated driver modules 5 are arranged or soldered. The whole surface of the support body 2 is coated or covered with a light-transmitting material. The light-transmitting material is a plastic. Electrical connecting cables as connecting elements 7 are fed out of the light-transmitting material. These connecting elements 7 are electrically connected to the metallization regions 3. To put the LED module 1 into operation, it is only necessary to connect the connecting elements 7 to a power supply network. Here, the connecting elements 7 are fed out to the side under the light-transmitting material 6, i.e. the cover.

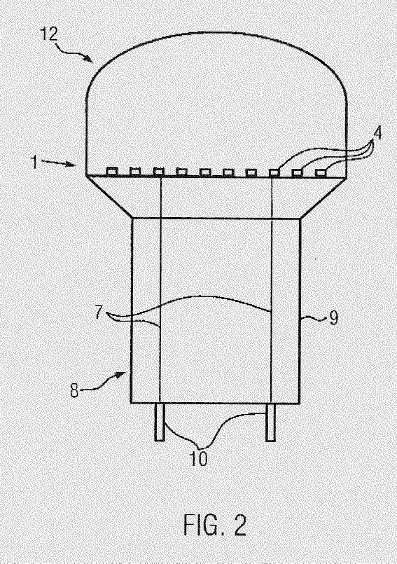

FIG. 2 shows a lamp 8 in which the encapsulated LED module 1 according to the invention with the LEDs 4 is fitted. The lamp consists of a ceramic lamp base 9 (or other materials) on which the LED module 1 rests. The connecting elements 7, in this case connecting wires, feed through the lamp base to two pins 10. Optionally, a glass dome 12, which covers the LED module 1 and has an internal coating (converter layer), is placed on the lamp base 9.

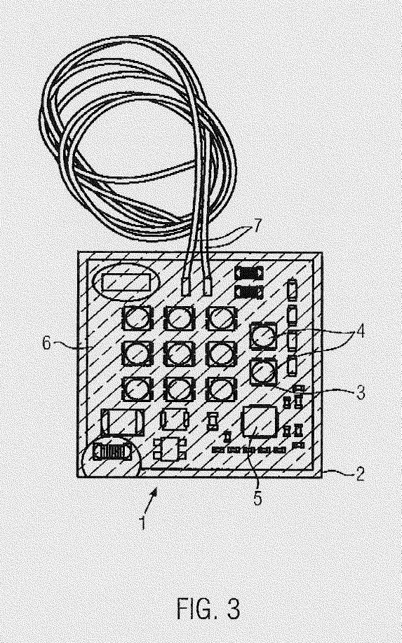

FIG. 3 shows an example of a square LED module 1 with numerous fitted driver modules 5 and LEDs 4 on the metallization regions 3. The whole surface of the support body 2 is covered with the light-transmitting material 6. The connecting elements 7 are fed out of the LED module to the side under the light-transmitting material 6.

1. An LED module having a support body, on the surface of which metallization regions forming a circuit board are arranged and on which LEDs are mounted, characterized in that, in addition to the LEDs, the driver modules thereof are also mounted on the metallization regions and at least the LEDs together with the driver modules are covered by a light-transmitting material, electrical connecting elements are connected to the LEDs or driver modules and are fed out of the translucent material.

2. The LED module according to claim 1, characterized in that the support body is curved, i.e. not in the form of a plate.

3. The LED module according to claim 1, characterized in that the support body is made of a ceramic material.

4. The LED module according to claim 1 characterized in that the support body is made of a ceramic composite, glass, glass ceramic or high-purity crystalline ceramics.

5. The LED module according to claim 1, characterized in that the metallization regions are soldered to, glued to or sintered with the support body.

6. The LED module according to claim 1, characterized in that the electrical connecting elements are connecting leads or plug-in connectors.

7. The LED module according to claim 1, characterized in that the light-transmitting material covers the whole surface of the support body on which the LEDs and the driver modules are located.

8. The LED module according to claim 1, characterized in that the light-transmitting material is a plastic.
